(19) United States
(12) Patent Application Publication
(10) Pub. No.: US 2025/0259937 A1
(43) Pub. Date: Aug. 14, 2025

(54) SQUARE THERMAL VIA

(71) Applicant: QUALCOMM Incorporated, San Diego, CA (US)

(72) Inventors: Heun Gun SHIN, San Diego, CA (US); Kyudong KANG, Seoul (KR)

(21) Appl. No.: 18/438,421

(22) Filed: Feb. 10, 2024

(51) Int. Cl. H01L 23/538; H01L 21/48; H01L 25/16

(52) U.S. Cl. CPC H01L 23/5386; H01L 21/4857; H01L 23/5383; H01L 25/16

(57) ABSTRACT

Disclosed are examples of semiconductor modules that includes a die (e.g., a power amplifier) which may generate significant amount of heat when in operation. The disclosed semiconductor module may include non-circular (e.g., square) shaped thermal vias to carry the heat away from the die.

### BACKGROUND OF THE DISCLOSURE

### 1. Field of the Disclosure

This disclosure relates generally to die packages or modules, and more specifically, but not exclusively, to die packages/modules that includes non-circular—e.g., square—thermal vias and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/modules, RFIC chips such as switches (SW), low noise amplifiers (LNA), power amplifiers (PA), digital amplifiers (DA), filters, etc. are placed side-by-side in a package, e.g., for an RF frontend module. Unfortunately, some of the chips or dies generate significant amount of heat during their operation, which can be damaging. Accordingly, there is a need for systems, apparatus, and methods that overcome the deficiencies of conventional semiconductor modules including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor module is disclosed. The semiconductor module may comprise a die. The die may comprise one or more die pads on a lower surface of the die. The semiconductor module may also comprise a first substrate below the die. The semiconductor module may further comprise one or more first thermal vias formed within the first substrate. The one or more first thermal vias may be thermally coupled with the one or more die pads. Also, the one or more first thermal vias have a shape that is non-circular. The semiconductor module may yet comprise a second substrate below the first substrate. The first and second substrates may be formed from different materials. The semiconductor module may yet further comprise one or more second thermal vias formed within the second substrate. The one or more second thermal vias may be thermally coupled with the one or more first thermal vias.

A method of fabricating an exemplary semiconductor module is disclosed. The method may comprise providing a die. The die may comprise one or more die pads on a lower surface of the die. The method may also comprise forming a first substrate below the die. The method may further comprise forming one or more first thermal vias within the first substrate. The one or more first thermal vias may be thermally coupled with the one or more die pads. Also, the one or more first thermal vias have a shape that is non-circular. The method may yet comprise forming a second substrate below the first substrate. The first and second substrates may be formed from different materials. The method may yet further comprise forming one or more second thermal vias within the second substrate. The one or more second thermal vias may be thermally coupled with the one or more first thermal vias.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a cross section of an example of a conventional semiconductor module, FIG. 1B illustrates a portion of the conventional semiconductor module of FIG. 1A, and FIG. 1C illustrates a top-down view of the conventional semiconductor module portion of FIG. 1B.

FIG. 2 illustrates relative areas covered by a square and a circle of similar dimensions.

FIG. 3A illustrates a cross section of an example of a semiconductor module in accordance with one or more aspects of the disclosure, FIG. 3B illustrates a portion of the semiconductor module of FIG. 3A, and FIG. 3C illustrates a top-down view of the conventional semiconductor module portion of FIG. 3B.

FIG. 4 illustrates a top-down view of another embodiment of a semiconductor module in accordance with one or more aspects of the disclosure.

FIGS. 5A-5J illustrate examples of stages of fabricating a conventional semiconductor module.

FIGS. 6A-6H illustrate examples of stages of fabricating a semiconductor module in accordance with one or more aspects of the disclosure.

FIGS. 7-9 illustrate flow charts of example methods of manufacturing a semiconductor module in accordance with at one or more aspects of the disclosure.

FIG. 10 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor modules and methods for fabricating the same. In an aspect, the semiconductor module may comprise a die comprising one or more die pads on a lower surface of the die, a first substrate below the die; one or more first thermal vias formed within the first substrate, a second substrate below the first substrate, and one or more second thermal vias formed within the second substrate. The one or more first thermal vias may be thermally coupled with the one or more die pads, and the one or more second thermal vias may be thermally coupled with the one or more first thermal vias. The one or more first thermal vias have a shape that is non-circular that allows more heat to be carried away from the die through the die pads.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

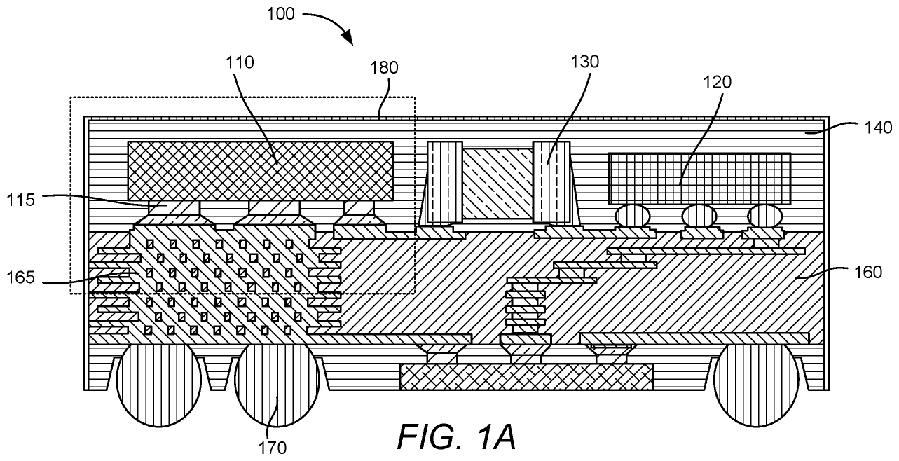

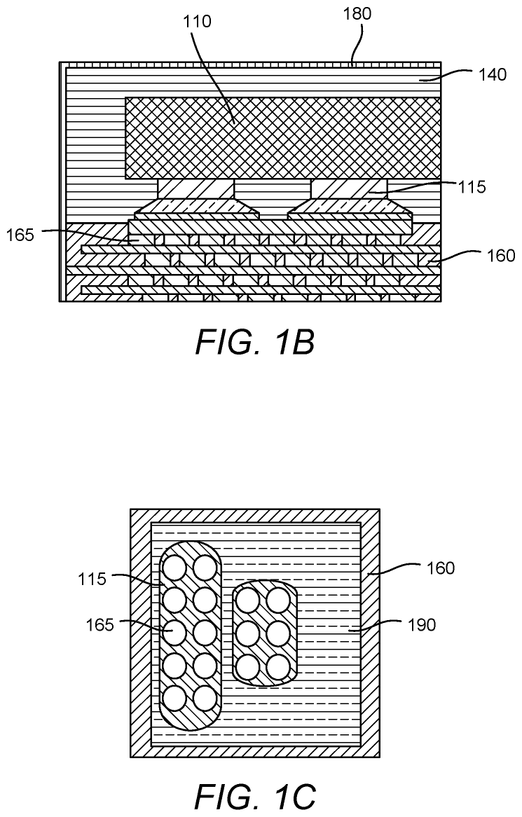

As indicated above, some chips or dies of a semiconductor module may generate a significant amount of heat that needs to be removed for proper operation of the semiconductor module. FIG. 1A illustrates an example of a conventional semiconductor module 100, which in this instance is a radio frequency front end (RFFE) module. The semiconductor module 100 includes a die 110, which is a power amplifier (PA) in this instance. The die 110 includes a plurality of die pads 115 on a lower surface of the die 110. The semiconductor module 100 also includes another die 120 (e.g., low noise amplifier (LNA)), and an integrated passive device (IPD) 130 (e.g., inductor, capacitor). The die 110, the another die 120, and the IPD 130 are encapsulated by a mold 140. A prepreg substrate 160 (or simply prepreg) is formed below the die 110 and below the mold 140. A plurality of thermal vias 165, made of copper (Cu), are formed within the prepreg 160. There are solder balls 170 in contact with the thermal vias 165. Also, a shield 180 surrounds the semiconductor module 100.

In FIG. 1A, a portion is highlighted by a dashed box. FIG. 1B is a magnified illustration of the highlighted portion of FIG. 1A. The die 110, i.e., the power amplifier, generates a significant amount of heat during its operation. The generated heat is carried away from the die 110 by the thermal vias 165, which are in direct contact with the die pads 115. The removed heat is carried to the solder balls 170, and ultimately expelled external to the semiconductor module 100.

FIG. 1C illustrates a top-down view of the portion of the semiconductor module 100 illustrated in FIG. 1B. In particular, FIG. 1C illustrates the view below the die 110. As seen, the semiconductor module 100 further includes a ground plane 190 (not specifically indicated in FIGS. 1A-1B). The plurality of thermal vias 165 and the ground plane 190 are formed within the prepreg 160. The thermal vias 165 are shown as being in contact with the die pads 115.

In manufacturing of the conventional semiconductor module 100, laser drilling is used to form the holes in the prepreg 160. The holes are filled with copper (Cu) to form the thermal vias 165. As seen in FIG. 1C, due to the nature of laser drilling, the shape of the thermal vias is a circle. Hence, there is a limitation in the amount of Cu that can be used to form the vias. As such, there is also a limitation in the amount of heat that can be removed from the die 110 through the thermal vias 165.

To address these and other issues of the conventional semiconductor module, it is proposed to provide an increased heat removing capability of the thermal vias by increasing amount of metal in the thermal vias. It is desirable to achieve this aspect while maintaining a similar separation distance between adjacent thermal vias. One way this can be achieved is through forming thermal vias with different shapes, i.e., non-circular shaped. In an aspect, a rectangular shape can achieve this improvement over a circular shape. In particular, a square may be used.

This is illustrated in FIG. 2. In FIG. 2, there are four circles inscribed in four squares. The circles may represent conventionally shaped thermal vias and the squares (e.g., non-circles) may represent a shape of the thermal vias in accordance with one or more aspects of the present disclosure. Each of the circles have a diameter of “A”. Also, edge-to-edge distance between adjacent circles is “B”. Likewise, each of the squares have an edge length of “A”, and an edge-to-edge distance of “B” between adjacent squares.

However, note that the area of the square is larger than the circle of similar dimensions. This implies that by forming the thermal vias with non-circular shaped (e.g., rectangle, square, etc.), greater amount of metal can be used within similar dimensions. This in turn implies that heat removal capacity can be increased within specified dimensions of a design criteria.

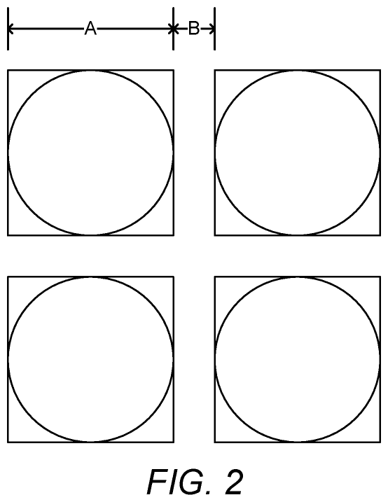

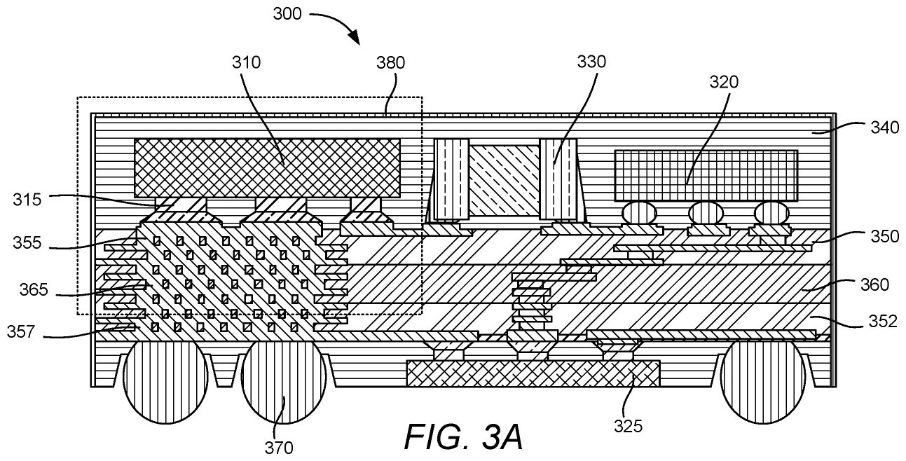

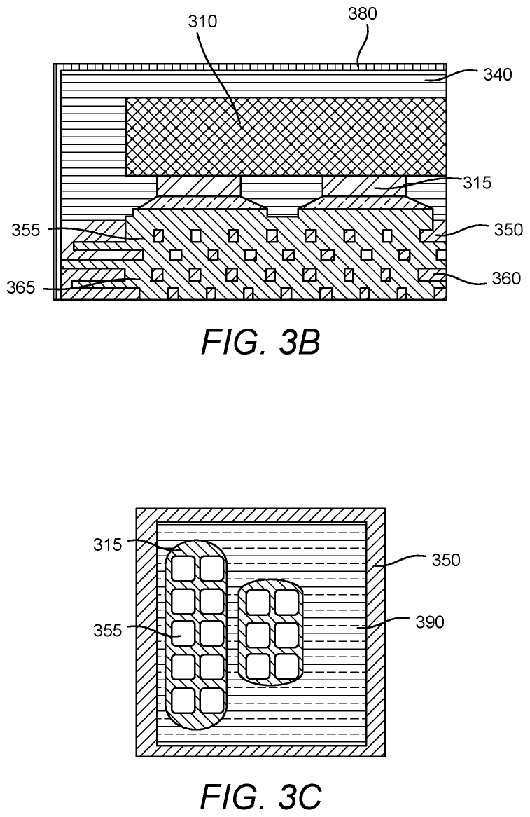

FIG. 3A illustrates an example of a semiconductor module 300 in accordance with one or more aspects of the disclosure. In an aspect, the semiconductor module 300 may be an RFFE) module. The semiconductor module 300 may include a die 310. The die 310 may be a power amplifier (PA), a digital amplifier (DA), or any other die or chip in which removal of heat may be beneficial in the operation of the die or the chip.

The die 310 may include one or more die pads 315 on a lower surface of the die 310. Heat generated by the die 310 during its operation may be carried to the die pads 315. Note that some or all of the die pads 315 may also carry electrical signals to and/or from the die 310 during its operation.

The semiconductor module 300 may also include another die 320 (e.g., low noise amplifier (LNA)), and an integrated passive device (IPD) 330 (e.g., inductor, capacitor). The die 310, the another die 320, and the IPD 330 may be encapsulated by a mold 340. Yet another die 325 (e.g., controller) may be provided. In this instance, the die 325 is shown as being provided on a lower portion of the semiconductor module 300. This is just to indicate that there are no limits on a number of dies that may be included in the semiconductor module 300.

The semiconductor module 300 may include a first substrate 350 below the die 310. The first substrate 350 may also be below the another die 320 and/or the IPD 330. In an aspect, the first substrate 350 may be in contact with the mold 340. One or more first thermal vias 355 may be formed within the first substrate 350. The first thermal vias 355 may be formed from metal such as copper (Cu). One, some or all of the first thermal vias 355 may be thermally coupled with the die pads 315. For example, one, some, or all of the first thermal vias 355 may be in direct contact with one, some, or all of the die pads 315. Through thermal communication, heat generated from the die 310 may be carried away by the first thermal vias 355. Note that some or all of the first thermal vias 355 may also carry electrical signals to and/or from the die 310 during its operation.

A second substrate 360 may be formed below the first substrate 350. In an aspect, the second substrate 360 may be formed from or comprise a prepreg. That is, the first and second substrates 350, 360 may be formed from different materials. One or more second thermal vias 365 may be formed within the second substrate 360. The second thermal vias 365 may be formed from metal such as copper (Cu). That is, in an aspect, the first and second thermal vias 355, 365 may be formed from a same metal. One, some or all of the second thermal vias 365 may be thermally coupled with one, some or all of the first thermal vias 355. For example, one, some, or all of the second thermal vias 365 may be in direct contact with one, some, or all of the first thermal vias 355. Through thermal communication, heat generated from the die 310 may be carried away by the second thermal vias 365 through the first thermal vias 355. Note that some or all of the second thermal vias 365 may also carry electrical signals to and/or from the die 310 during its operation through the first thermal vias 355. A shield 380 may surround the semiconductor module 300, at least partially. In an aspect the shield 380 may shield the semiconductor module 300 from electromagnetic interferences.

In FIG. 3A, a portion is highlighted by a dashed box. FIG. 3B is a magnified illustration of the highlighted portion of FIG. 3A. The die 310 may generate a significant amount of heat during its operation. For example, the die 310 may be a power amplifier, a digital amplifier, etc. The generated heat may be carried away from the die 310 by the first and second thermal vias 355, 365. The removed heat may be carried to interconnects 370 (e.g., solder balls), and ultimately expelled external to the semiconductor module 300.

In an aspect, the shape of the first thermal vias 355 may be non-circular. For example, they may be rectangular. Even more specific, the shape may be a square. This is shown in FIG. 3C, which illustrates a top-down view of the portion of the semiconductor module 300 illustrated in FIG. 3B. In particular, FIG. 3C illustrates the view below the die 310. As seen, the semiconductor module 300 may further include a ground plane 390 (not specifically indicated in FIGS. 3A-3B). The first thermal vias 355 and the ground plane 390 may be formed within the first substrate 350. The first thermal vias 355 are shown as being in contact with the die pads 315.

Recall from above, that laser drilling forms circular shapes. This means that laser drilling is NOT used to form the via holes in the first substrate 350. This implies that the first substrate 350 should be a material in which alternative processes—e.g., light exposure and development—can be used to form the via holes with desirable shapes (e.g., squares). One such material is photo imageable dielectric (PID). Thus, in an aspect, the first substrate 350 may comprise a PID.

In an aspect, laser drilling may be used to form the holes in the second substrate 360. Thus, the shape of the second thermal vias 365 may be a circle. Note that even though the second thermal vias 365 are circular, the enhanced heat removal capability of the first thermal vias 355 allows the combination of the first and second thermal vias 355, 365 to be more efficient at heat removal than circular thermal vias alone.

Referring back to FIG. 3A, a third substrate 352 formed below the second substrate 360. In an aspect, the third substrate 352 may be in contact with the second substrate 360. One or more third thermal vias 357 may be formed within the third substrate 352. The third thermal vias 357 may be formed from metal such as copper (Cu). One, some or all of the third thermal vias 357 may be thermally coupled with the one, some or all of the second thermal vias 365. For example, one, some, or all of the third thermal vias 357 may be in direct contact with one, some or all of the second thermal vias 365. Through thermal communication, heat generated from the die 310 may be carried away by the first, second and third thermal vias 355, 365, 357. Note that some or all of the third thermal vias 357 may also carry electrical signals to and/or from the die 310 during its operation through the first and second thermal vias 355, 365.

In an aspect, the shape of the third thermal vias 357 may be non-circular. For example, they may be rectangular. Even more specific, the shape may be a square. As such, the third substrate 352 may comprise PID or any other material in which processes alternative to laser drilling (e.g., exposure and development) may be used to form the via holes of desired shapes.

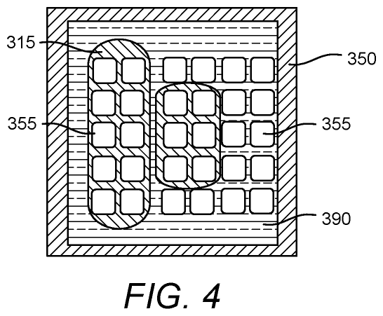

Referring to FIG. 3C, note that the first thermal vias 355 are in direct contact with the die pad 315. However, this is not a strict requirement. FIG. 4 illustrates a top-down view of another embodiment of a semiconductor module in accordance with one or more aspects of the disclosure. As seen in FIG. 4, note that some of the first thermal vias 355 may be in direct contact with the ground plane 390, but need not be in direct contact with the die pads 315. Such first thermal vias 355 may still aid in dissipating heat from the die 310.

The thermal vias with non-circular shapes (e.g., first and third thermal vias 355, 357) may include the following technical advantages (not necessarily exhaustive):
Larger metal volume of the non-circular (e.g., square) vias under the heat generating die pads allows for a better heat sink to reduce the module temperature, improve performance and power consumption. Also, the number of vias can be reduced, which can contribute to savings in manufacturing cost compared to laser blind via process.
The proposed thermal vias can increase the metal volume, and thus help to drop temperature of the heat generating die. Electrically, the increase in the metal volume can also reduce the resistance, and thus improve performance. Blind via connections can be removed and thereby improve mechanical structure.
Standard substrate fabrication process can be used. Therefore, cost can be minimized.
In implementations such as RFFE, substrate design may be improved for enhanced thermal performance along with cost reduction.
The non-circular (e.g., square) holes for the thermal vias can be photo defined and filled by a vial filling process. Such processes are compatible with existing infrastructure.
The non-circular (e.g., square) hole vias can replace the blind via to maintain overall substrate thickness and dimple targets, and maintain a structure that will have little to no impact on module assembly methods.
The non-circular (e.g., square) vias may be filled out using copper, which is same as the blind vias.

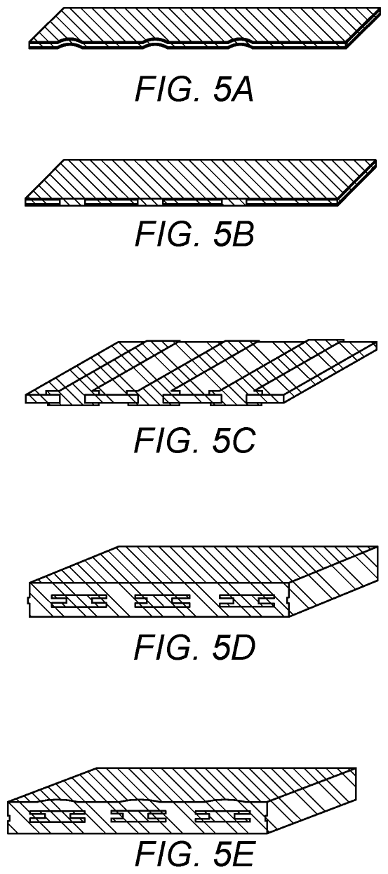

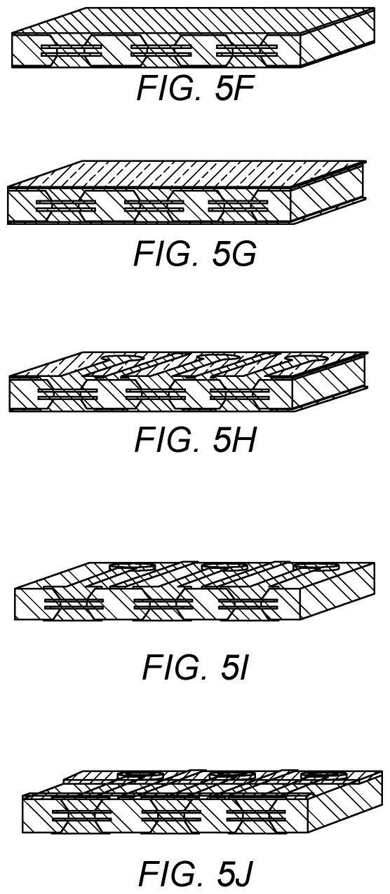

FIGS. 5A-5J illustrate examples of stages of fabricating a conventional semiconductor module, such as the conventional semiconductor module 100. FIG. 5A illustrates a stage in which an inner substrate layer is provided and laser drilled to form the substrate. FIG. 5B illustrates a stage in which the substrate is plated with copper.

FIG. 5C illustrates a stage in which the substrate is patterned through lithography.

FIG. 5D illustrates a stage in which hot press is performed on the substrate with copper foil.

FIG. 5E illustrates a stage in which laser drill and desmear is performed to remove the resin ash.

FIG. 5F illustrates a stage in which electroless copper plating is performed on the copper foil.

FIG. 5G illustrates a stage in which lithography is performed to fill out the copper. Sacrificial film is used in the process.

FIG. 5H illustrates a stage in which pattern plating is performed.

FIG. 5I illustrates a stage in which sacrificial film is stripped and etched.

FIG. 5J illustrates a stage in which solder resist process is performed to make the final composite substrate.

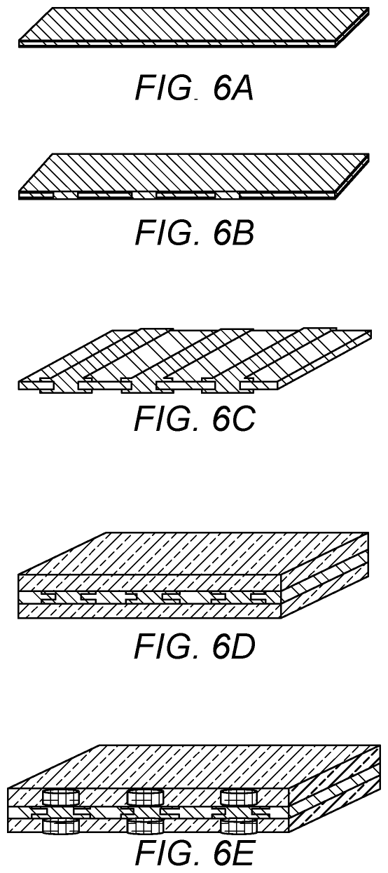

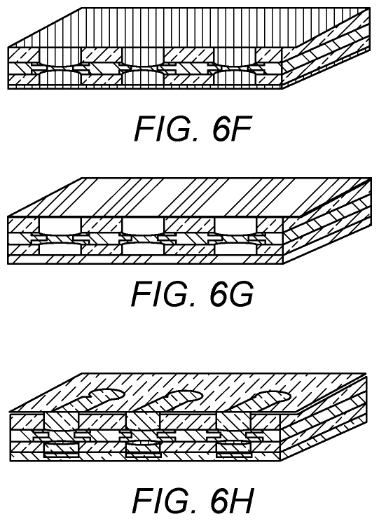

FIGS. 6A-6H illustrate examples of stages of fabricating a semiconductor module-such as the semiconductor module 200—in accordance with at one or more aspects of the disclosure. One significant difference between the stages illustrated in FIGS. 5A-5J for the conventional semiconductor module and the stages illustrated in FIGS. 6A-6H for the proposed semiconductor module is in the via formation.

The stages illustrated in FIGS. 6A-6C may be similar to the stages illustrated in FIGS. 5A-5C. FIG. 6A illustrates a stage in which an inner substrate layer may be provided and laser drilled to form a substrate, such as the second substrate 360.

FIG. 6B illustrates a stage in which the substrate may be plated with copper (Cu), e.g., to form the second thermal vias 365.

FIG. 6C illustrates a stage in which the Cu plated second substrate 360 may be patterned, e.g., through lithography.

FIG. 6E illustrates a stage in which first and third substrates 350, 352 may be exposed and developed to form holes therein corresponding to the first and third thermal vias 355, 357.

FIG. 6F illustrates a stage in which the first and third substrates 350, 352 may be plated with the seed layer with electroless copper to fill the holes. Desmearing may also be performed to remove excess resin and copper.

FIG. 6G illustrates a stage in which the first and third substrates 350, 352 may be laminated with dry film to fill the holes to form the first and third thermal vias 355, 357.

FIG. 6H illustrates a stage in which the first and third substrates 350, 352 may be pattern plated.

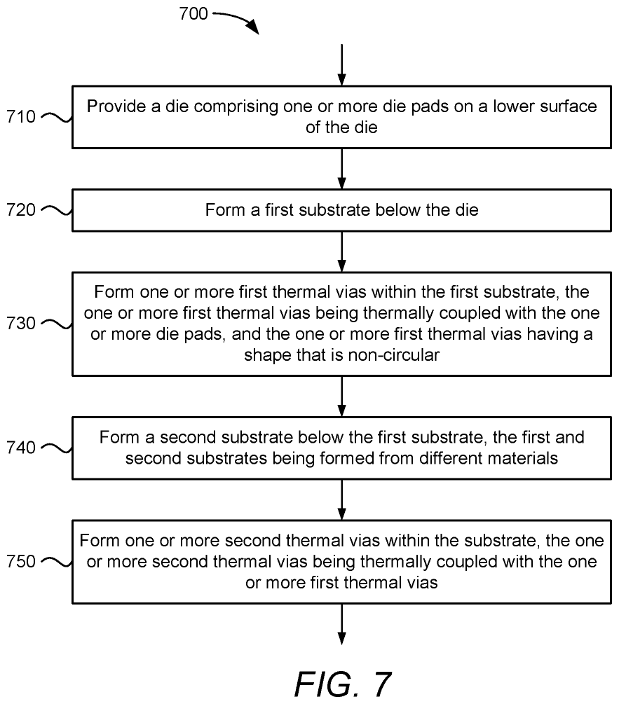

FIG. 7 illustrates a flow chart of an example method 700 of fabricating a semiconductor module, such as the semiconductor module 200, in accordance with at one or more aspects of the disclosure.

In block 710, a die 310 may be provided. The die 310 may comprise one or more die pads 315 on a lower surface of the die 310.

In block 720, a first substrate 350 may be formed below the die 310.

In block 730, one or more first thermal vias 355 may be formed within the first substrate 350. The one or more first thermal vias 355 may be thermally coupled with the one or more die pads 315. The one or more first thermal vias 355 may have a non-circular (e.g., rectangle, square, etc.) shape.

In block 740, a second substrate 360 may be formed below the first substrate 350. The first and second substrates 350, 360 may be formed from different materials (e.g., PID, prepreg).

In block 750, one or more second thermal vias 365 may be formed within the second substrate 360. The one or more second thermal vias 365 may be thermally coupled with the one or more first thermal vias 355.

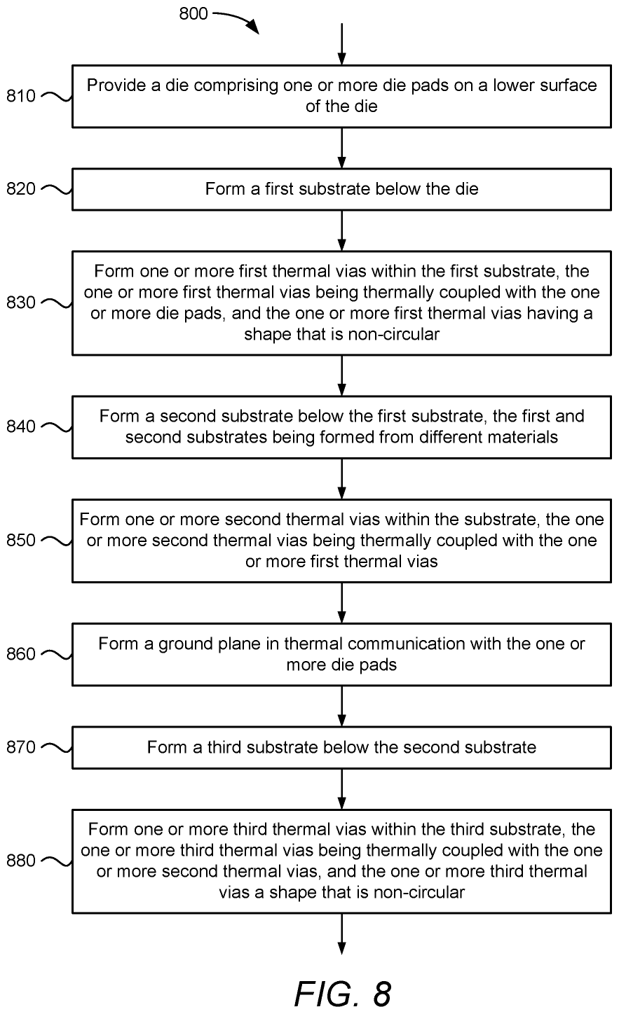

FIG. 8 illustrates a flow chart of an example method 800 of fabricating a semiconductor module, such as the semiconductor module 200 in accordance with at one or more aspects of the disclosure. FIG. 8 may be viewed as being more comprehensive than FIG. 7.

Block 810 may be similar to block 710. That is, in block 810, a die 310 may be provided. The die 310 may comprise one or more die pads 315 on a lower surface of the die 310.

Block 820 may be similar to block 720. That is, in block 820, a first substrate 350 may be formed below the die 310.

Block 830 may be similar to block 730. That is, in block 830, one or more first thermal vias 355 may be formed within the first substrate 350. The one or more first thermal vias 355 may be thermally coupled with the one or more die pads 315. The one or more first thermal vias 355 may have a non-circular (e.g., rectangle, square, etc.) shape.

Block 840 may be similar to block 740. That is, in block 840, a second substrate 360 may be formed below the first substrate 350. The first and second substrates 350, 360 may be formed from different materials (e.g., PID, prepreg).

Block 850 may be similar to block 750. That is, in block 850, one or more second thermal vias 365 may be formed within the second substrate 360. The one or more second thermal vias 365 may be thermally coupled with the one or more first thermal vias 355.

In block 860, a ground plane 390 may be formed. The ground plane 390 may be thermally coupled with the one or more die pads 315.

In block 870, a third substrate 352 may be formed below the second substrate 360.

In block 880, one or more third thermal vias 357 may be formed within the third substrate 352. The one or more third thermal vias 357 may be thermally coupled with the one or more second thermal vias 365. The one or more third thermal vias 357 may have a non-circular (e.g., rectangle, square, etc.) shape.

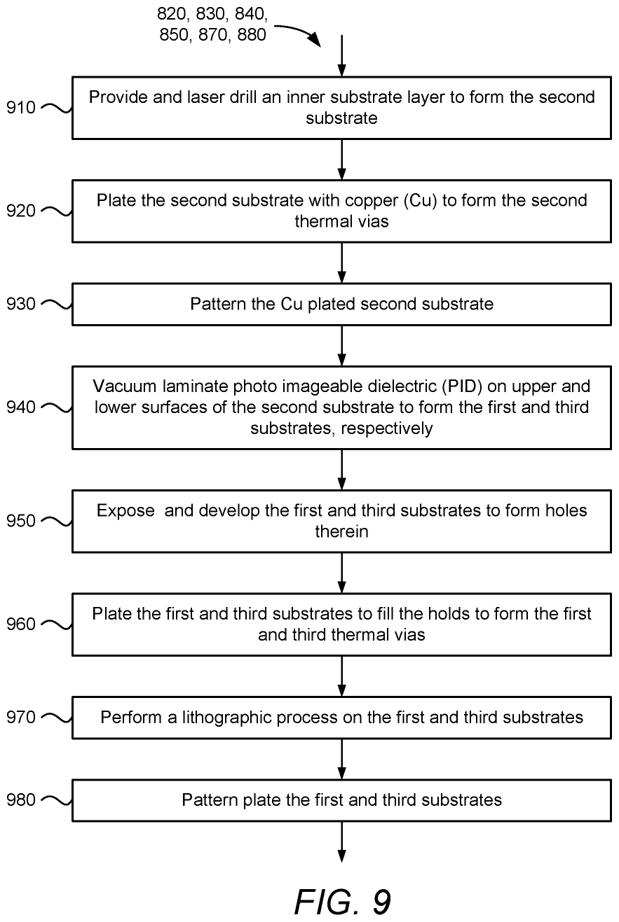

FIG. 9 illustrates a flow chart of an example process to implement blocks 820-880. In block 910, an inner substrate layer may be provided and laser drilled to form a substrate, such as the second substrate 360.

In block 920, the substrate may be plated with copper (Cu), e.g., to form the second thermal vias 365.

In block 930, the Cu plated second substrate 360 may be patterned, e.g., through lithography.

In block 940, the first and third substrates 350, 352 may be exposed and developed to form holes therein corresponding to the first and third thermal vias 355, 357.

In block 950, first and third substrates 350, 352 may be plated with the seed layer by electroless copper to fill the holes. Desmearing may also be performed (optional) to remove excess resin and copper.

In block 960, the first and third substrates 350, 352 may be laminated with dry film to fill the holes to form the first and third thermal vias 355, 357.

In block 970, the first and third substrates 350, 352 may be pattern plated.

The following should be noted regarding the flow indicated in FIGS. 7-9. Unless otherwise indicated, the flow of blocks do not necessarily limit the ordering in which the blocks may be performed. In other words, the blocks may be performed in any order that is logical.

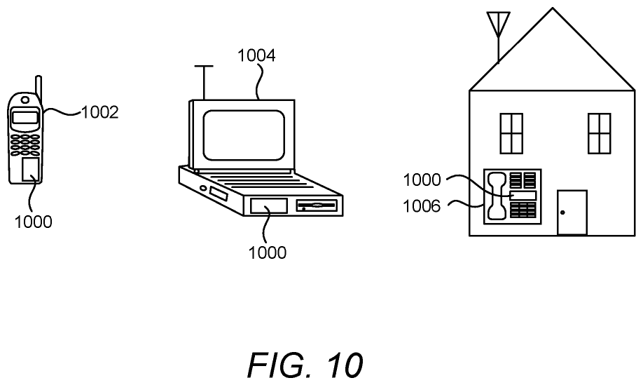

FIG. 10 illustrates various electronic devices 1000 that may be integrated with any of the aforementioned semiconductor module in accordance with various aspects of the disclosure. For example, a mobile phone device 1002, a laptop computer device 1004, and a fixed location terminal device 1006 may each be considered generally user equipment (UE) and may include one or more semiconductor modules (e.g., semiconductor module 200) as described herein. The devices 1002, 1004, 1006 illustrated in FIG. 10 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor module, comprising: a die comprising one or more die pads on a lower surface of the die; a first substrate below the die; one or more first thermal vias formed within the first substrate, the one or more first thermal vias being thermally coupled with the one or more die pads, and the one or more first thermal vias having a shape that is non-circular; a second substrate below the first substrate, the first and second substrates being formed from different materials; and one or more second thermal vias formed within the second substrate, the one or more second thermal vias being thermally coupled with the one or more first thermal vias.

Clause 2: The semiconductor module of clause 1, wherein the first substrate comprises a photo imageable dielectric (PID), or wherein the second substrate comprises a prepreg, or both.

Clause 3: The semiconductor module of any of clauses 1-2, wherein the shape of the one or more first thermal vias is a square.

Clause 4: The semiconductor module of any of clauses 1-3, wherein at least one first thermal via is in direct contact with at least one die pad.

Clause 5: The semiconductor module of any of clauses 1-4, wherein a shape of the one or more second thermal vias is a circle.

Clause 6: The semiconductor module of any of clauses 1-5, wherein the one or more first thermal vias is in direct contact with at least one second thermal via.

Clause 7: The semiconductor module of any of clauses 1-6, wherein the one or more first thermal vias and the one or more second thermal vias are formed from a same metal.

Clause 8: The semiconductor module of clause 7, wherein the one or more first thermal vias and the one or more second thermal vias are formed from copper (Cu).

Clause 9: The semiconductor module of any of clauses 1-8, further comprising: a ground plane thermally coupled with the one or more die pads, wherein at least one first thermal via is in direct contact with the ground plane but not in direct contact with any of the one or more die pads.

Clause 10: The semiconductor module of any of clauses 1-9, further comprising: a third substrate below the second substrate; and one or more third thermal vias formed within the third substrate, the one or more third thermal vias being thermally coupled with the one or more second thermal vias, and the one or more third thermal vias having a shape that is non-circular.

Clause 11: The semiconductor module of clause 10, wherein the third substrate comprises a photo imageable dielectric (PID).

Clause 12: The semiconductor module of clauses 10-11, wherein the one or more third thermal vias is in direct contact with at least one second thermal via.

Clause 13: The semiconductor module of any of clauses 10-12, wherein the shape of the one or more third thermal vias is a square.

Clause 14: The semiconductor module of any of clauses 10-13, wherein the one or more third thermal vias are formed from copper (Cu).

Clause 15: The semiconductor module of any of clauses 1-14, wherein the semiconductor module is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 16: A method of fabricating a semiconductor module, the method comprising: providing a die comprising one or more die pads on a lower surface of the die; forming a first substrate below the die; forming one or more first thermal vias within the first substrate, the one or more first thermal vias being thermally coupled with the one or more die pads, and the one or more first thermal vias having a shape that is non-circular; forming a second substrate below the first substrate, the first and second substrates being formed from different materials; and forming one or more second thermal vias within the second substrate, the one or more second thermal vias being thermally coupled with the one or more first thermal vias.

Clause 17: The method of clause 16, wherein the first substrate comprises a photo imageable dielectric (PID), or wherein the second substrate comprises a prepreg, or both.

Clause 18: The method of any of clauses 16-17, wherein the shape of the one or more first thermal vias is a square.

Clause 19: The method of any of clauses 16-18, wherein at least one first thermal via is in direct contact with at least one die pad.

Clause 20: The method of any of clauses 16-19, wherein a shape of the one or more second thermal vias is a circle.

Clause 21: The method of any of clauses 16-20, wherein the one or more first thermal vias is in direct contact with at least one second thermal via.

Clause 22: The method of any of clauses 16-21, wherein the one or more first thermal vias and the one or more second thermal vias are formed from a same metal.

Clause 23: The method of clause 22, wherein the one or more first thermal vias and the one or more second thermal vias are formed from copper (Cu).

Clause 24: The method of any of clauses 16-23, further comprising: forming a ground plane thermally coupled with the one or more die pads, wherein at least one first thermal via is in direct contact with the ground plane but not in direct contact with any of the one or more die pads.

Clause 25: The method of any of clauses 16-24, further comprising: forming a third substrate below the second substrate; and forming one or more third thermal vias within the third substrate, the one or more third thermal vias being thermally coupled with the one or more second thermal vias, and the one or more third thermal vias having a shape that is non-circular.

Clause 26: The method of clause 25, wherein the third substrate comprises a photo imageable dielectric (PID).

Clause 27: The method of any of clauses 25-26, wherein the one or more third thermal vias is in direct contact with at least one second thermal via.

Clause 28: The method of any of clauses 25-27, wherein the shape of the one or more third thermal vias is a square.

Clause 29: The method of any of clauses 25-28, wherein the one or more third thermal vias are formed from copper (Cu).

Clause 30: The method of any of clauses 25-29, wherein forming the first substrate, forming the one or more first thermal vias, forming the second substrate, forming the one or more second thermal vias, forming the third substrate, and forming one or more third thermal vias comprise: providing and laser drilling an inner substrate layer to form the second substrate; plating the second substrate with copper (Cu) to form the second thermal vias; patterning the Cu plated second substrate; exposing and developing the first and third substrates to form holes therein corresponding to the first and third thermal vias; plating the first and third substrates with seed layer to fill the holes; laminating the first and third substrates with dry film to fill the holes to form the first and third thermal vias; and pattern plating the first and third substrates.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor module, comprising:
a die comprising one or more die pads on a lower surface of the die;
a first substrate below the die;
one or more first thermal vias formed within the first substrate, the one or more first thermal vias being thermally coupled with the one or more die pads, and the one or more first thermal vias having a shape that is non-circular;
a second substrate below the first substrate, the first and second substrates being formed from different materials; and
one or more second thermal vias formed within the second substrate, the one or more second thermal vias being thermally coupled with the one or more first thermal vias.

2. The semiconductor module of claim 1,
wherein the first substrate comprises a photo imageable dielectric (PID), or
wherein the second substrate comprises a prepreg, or
both.

3. The semiconductor module of claim 1, wherein the shape of the one or more first thermal vias is a square.

4. The semiconductor module of claim 1, wherein at least one first thermal via is in direct contact with at least one die pad.

5. The semiconductor module of claim 1, wherein a shape of the one or more second thermal vias is a circle.

6. The semiconductor module of claim 1, wherein the one or more first thermal vias is in direct contact with at least one second thermal via.

7. The semiconductor module of claim 1, wherein the one or more first thermal vias and the one or more second thermal vias are formed from a same metal.

8. The semiconductor module of claim 7, wherein the one or more first thermal vias and the one or more second thermal vias are formed from copper (Cu).

9. The semiconductor module of claim 1, further comprising:
a ground plane thermally coupled with the one or more die pads,
wherein at least one first thermal via is in direct contact with the ground plane but not in direct contact with any of the one or more die pads.

10. The semiconductor module of claim 1, further comprising:
a third substrate below the second substrate; and
one or more third thermal vias formed within the third substrate, the one or more third thermal vias being thermally coupled with the one or more second thermal vias, and the one or more third thermal vias having a shape that is non-circular.

11. The semiconductor module of claim 10, wherein the third substrate comprises a photo imageable dielectric (PID).

12. The semiconductor module of claim 10, wherein the one or more third thermal vias is in direct contact with at least one second thermal via.

13. The semiconductor module of claim 10, wherein the shape of the one or more third thermal vias is a square.

14. The semiconductor module of claim 10, wherein the one or more third thermal vias are formed from copper (Cu).

15. The semiconductor module of claim 1, wherein the semiconductor module is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

16. A method of fabricating a semiconductor module, the method comprising:
providing a die comprising one or more die pads on a lower surface of the die;
forming a first substrate below the die;
forming one or more first thermal vias within the first substrate, the one or more first thermal vias being thermally coupled with the one or more die pads, and the one or more first thermal vias having a shape that is non-circular;
forming a second substrate below the first substrate, the first and second substrates being formed from different materials; and
forming one or more second thermal vias within the second substrate, the one or more second thermal vias being thermally coupled with the one or more first thermal vias.

17. The method of claim 16,
wherein the first substrate comprises a photo imageable dielectric (PID), or
wherein the second substrate comprises a prepreg, or
both.

18. The method of claim 16, wherein the shape of the one or more first thermal vias is a square.

19. The method of claim 16, further comprising:
forming a ground plane thermally coupled with the one or more die pads,
wherein at least one first thermal via is in direct contact with the ground plane but not in direct contact with any of the one or more die pads.

20. The method of claim 19, wherein forming the first substrate, forming the one or more first thermal vias, forming the second substrate, forming the one or more second thermal vias, forming a third substrate, and forming one or more third thermal vias comprise:
providing and laser drilling an inner substrate layer to form the second substrate;
plating the second substrate with copper (Cu) to form the second thermal vias;
patterning the Cu plated second substrate;
exposing and developing the first and third substrates to form holes therein corresponding to the first and third thermal vias;
plating the first and third substrates with seed layer to fill the holes;
laminating the first and third substrates with dry film to fill the holes to form the first and third thermal vias; and
pattern plating the first and third substrates.
